(19) United States
(12) Patent Application Publication
(10) Pub. No.: US 2020/0143226 A1
(43) Pub. Date: May 7, 2020

(54) LOSSY COMPRESSION OF NEURAL NETWORK ACTIVATION MAPS

(71) Applicant: Samsung Electronics Co., Ltd., Suwon-si (KR)

(72) Inventor: Georgios GEORGIADIS, Porter Ranch, CA (US)

(21) Appl. No.: 16/223,092

(22) Filed: Dec. 17, 2018

Related U.S. Application Data
(60) Provisional application No. 62/756,067, filed on Nov. 5, 2018.

(51) Int. Cl. G06N 3/04; H03M 7/30

(52) U.S. Cl. CPC G06N 3/04; H03M 7/702

(57) ABSTRACT

A system and a method provide compression and decompression of an activation map of a layer of a neural network. For compression, the values of the activation map are sparsified and the activation map is configured as a tensor having a tensor size of H×W×C in which H represents a height of the tensor, W represents a width of the tensor, and C represents a number of channels of the tensor. The tensor is formatted into at least one block of values. Each block is encoded independently from other blocks of the tensor using at least one lossless compression mode. For decoding, each block is decoded independently from other blocks using at least one decompression mode corresponding to the at least one compression mode used to compress the block; and deformatted into a tensor having the size of H×W×C.

### CROSS-REFERENCE TO RELATED APPLICATION

This patent application claims the priority benefit under 35 U.S.C. § 119(e) of U.S. Provisional Patent Application No. 62/756,067, filed on Nov. 5, 2018, the disclosure of which is incorporated herein by reference in its entirety.

### TECHNICAL FIELD

The subject matter disclosed herein generally relates to a system and a method that provides lossy encoding/decoding of activation maps of a neural network to reduce memory requirements and accelerate execution of neural networks.

### BACKGROUND

Deep neural networks have recently been dominating a wide range of applications ranging from computer vision (image classification, image segmentation), natural language processing (word-level prediction, speech recognition, and machine translation) to medical imaging, and so on. Dedicated hardware has been designed to run the deep neural networks as efficiently as possible. On the software side, however, some research has focused on minimizing memory and computational requirements of these networks during runtime.

When attempting to train neural networks on embedded devices having limited memory, it is important to minimize the memory requirements of the algorithm as much as possible. During training the majority of the memory is actually occupied by the activation maps. For example, activation maps of current deep neural network systems consume between approximately 60% and 85% of the total memory required for the system. Consequently, reducing the memory footprint associated with activation maps becomes a significant part of reducing the entire memory footprint of a training algorithm.

In a neural network in which a Rectified Linear Unit (ReLU) is used as an activation function, activation maps tend to become sparse. For example, in the Inception-V3 model, the majority of activation maps has a sparsity of greater than 50%, and in some cases exceeds 90%. Therefore, there is a strong market need for a compression system that may target this sparsity to reduce the memory requirements of the training algorithm.

### SUMMARY

An example embodiment provides a system to compress an activation map of a layer of a neural network in which the system may include a processor programmed to initiate executable operations including: sparsifying, using the processor, a number of non-zero values of the activation map; configuring the activation map as a tensor having a tensor size of H×W×C in which H represents a height of the tensor, W represents a width of the tensor, and C represents a number of channels of the tensor; formatting the tensor into at least one block of values; and encoding the at least one block independently from other blocks of the tensor using at least one lossless compression mode. In one embodiment, the at least one lossless compression mode may be selected from a group including Exponential-Golomb encoding, Sparse-Exponential-Golomb encoding, Sparse-Exponential-Golomb-RemoveMin encoding, Golomb-Rice encoding, Exponent-Mantissa encoding, Zero-encoding, Fixed length encoding, and Sparse fixed length encoding. In another embodiment, the at least one lossless compression mode selected to encode the at least one block may be different from a lossless compression mode selected to encode another block of the tensor. In still another embodiment, the at least one block may be encoded independently from other blocks of the tensor using a plurality of the lossless compression modes.

Another example embodiment provides a method to compress an activation map of a neural network that may include: sparsifying, using a processor, a number of non-zero values of the activation map; configuring the activation map as a tensor having a tensor size of H×W×C in which H represents a height of the tensor, W represents a width of the tensor, and C represents a number of channels of the tensor; formatting the tensor into at least one block of values; and encoding the at least one block independently from other blocks of the tensor using at least one lossless compression mode. In one embodiment, the at least one lossless compression mode may be selected from a group including Exponential-Golomb encoding, Sparse-Exponential-Golomb encoding, Sparse-Exponential-Golomb-RemoveMin encoding, Golomb-Rice encoding, Exponent-Mantissa encoding, Zero-encoding, Fixed length encoding, and Sparse fixed length encoding. In another embodiment, the at least one lossless compression mode selected to encode the at least one block may be different from a lossless compression mode selected to compress another block of the tensor. In still another embodiment, encoding the at least one block further may include encoding the at least one block independently from other blocks of the tensor using a plurality of the lossless compression modes. In one embodiment, the method may further include outputting the at least one block encoded as a bit stream.

Still another example embodiment provides a method to decompress a sparsified activation map of a neural network that may include: decompressing, using a processor, a compressed block of values of a bitstream representing values of the sparsified activation map to form at least one decompressed block of values, the decompressed block of values being independently decompressed from other blocks of the activation map using at least one decompression mode corresponding to at least one lossless compression mode used to compress the at least one block; and deformatting the decompressed block to be part of a tensor having a size of H×W×C in which H represents a height of the tensor, W represents a width of the tensor, and C represents a number of channels of the tensor, the tensor being the decompressed activation map. In one embodiment, the at least one lossless compression mode may be selected from a group including Exponential-Golomb encoding, Sparse-Exponential-Golomb encoding, Sparse-Exponential-Golomb-RemoveMin encoding, Golomb-Rice encoding, Exponent-Mantissa encoding, Zero-encoding, Fixed length encoding, and Sparse fixed length encoding. In one embodiment, the method may further include sparsifying, using the processor, a number of non-zero values of the activation map; configuring the activation map as a tensor having a tensor size of H×W×C; formatting the tensor into at least one block of values; and encoding the at least one block independently from other blocks of the tensor using at least one lossless compression mode. In one embodiment, the at least one lossless compression mode selected to compress the at least one block may be different from a lossless compression mode selected to compress another block of the tensor of the received at least one activation map, and compressing the at least one block may further include compressing the at least one block independently from other blocks of the tensor of the received at least one activation map using a plurality of the lossless compression modes.

### BRIEF DESCRIPTION OF THE DRAWINGS

In the following section, the aspects of the subject matter disclosed herein will be described with reference to exemplary embodiments illustrated in the figures, in which:

FIG. 1 depicts a functional block diagram of an example embodiment of a system for lossy compression and decompression of activation maps of a neural network according to the subject matter disclosed herein;

FIG. 1A depicts a functional block diagram of a compressor according to the subject matter disclosed herein;

FIG. 1B depicts a functional block diagram of a decompressor according to the subject matter disclosed herein;

FIGS. 2A and 2B respectively depict example embodiments of an encoding method and a decoding method of activation maps of a deep neural network according to the subject matter disclosed herein; and

FIG. 3 depicts an operational flow of an activation map at a layer L of a neural network according to the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail not to obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing particular exemplary embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement the teachings of particular embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The subject matter disclosed herein relates to a system and a method that provides a lossy compression of neural network activation maps to reduce memory requirements and accelerate execution of neural networks. In one embodiment, three general stages are used provide a lossy compression pipeline: a sparsification stage, a quantization stage, and an entropy coding stage. In the sparsification stage, the activation maps of a neural network may be sparsified to reduce the number of non-zero values of the activation map. In the quantization stage, the activation maps of each layer are quantized. In the entropy coding stage, the quantized activation maps may be divided into smaller units, referred to herein as compress blocks, that are compressed using a variety of different compression modes. In one embodiment, the compress blocks are compressed to generate a bit stream representing the compressed activation maps of a layer of the neural network. The compress units may be decompressed, dequantized and reformatted into the original shape of the sparsified activation maps. The techniques disclosed herein may be performed using hardware having a relatively low complexity. It should be noted that even though sparsification makes the process lossy, the activation maps of a neural network may be compressed using the techniques disclosed herein without a drop in accuracy.

The encoding and decoding may be performed on the activation maps for each layer of the neural network independently from encoding of activation maps of other layers, and as needed by the training algorithm. While the lossless encoding/decoding technique disclosed herein may compress all degrees of sparsity (including 0% and nearly 100% sparsity), the technique disclosed herein may be optimized if the number of zero values in an activation map is relatively high. That is, the system and method disclosed herein achieves a higher degree of compression for a corresponding higher degree of sparsity. Additionally, the subject matter disclosed herein provides several modifications to existing compression algorithms that may be used to leverage the sparsity of the data of an activation map for a greater degree of compression.

In one embodiment, an encoder that may be configured to receive as an input a tensor of size H×W×C in which H corresponds to the height of the input tensor, W to the width of the input tensor, and C to the number of channels of the input tensor. The received tensor may be formatted into smaller blocks that are referred to herein as “compress units.” Compress units may be independently compressed using a variety of different compression modes. The output generated by the encoder is a bitstream of compressed compress units. When a compress unit is decompressed, it is reformatted into its original shape as at least part of a tensor of size H×W×C.

The techniques disclosed herein may be applied to reduce memory requirements for activation maps of neural networks that are configured to provide applications such as, but not limited to, computer vision (image classification, image segmentation), natural language processing (word-level prediction, speech recognition, and machine translation) and medical imaging. The neural network applications may be used within autonomous vehicles, mobile devices, robots, and/or other low-power devices (such as drones). The techniques disclosed herein reduce memory consumption by a neural network during training and/or as embedded in a dedicated device. The techniques disclosed herein may be implemented on a general-purpose processing device or in a dedicated device.

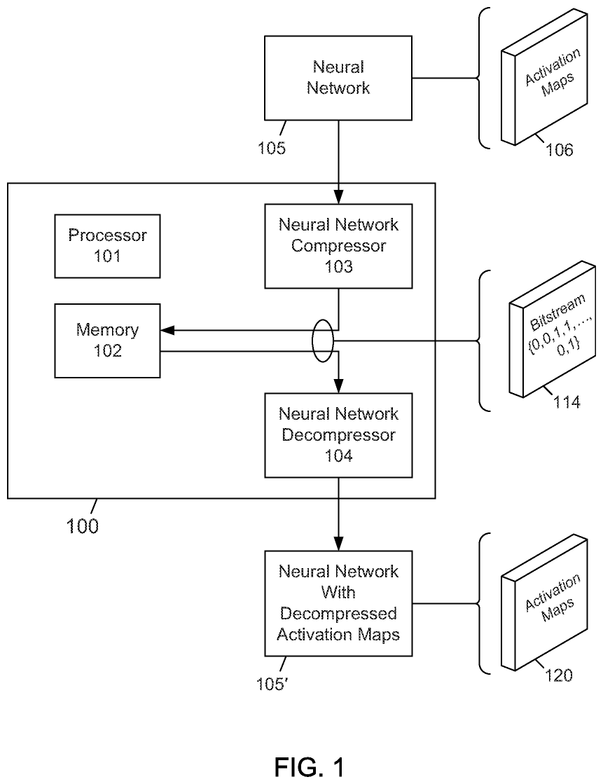

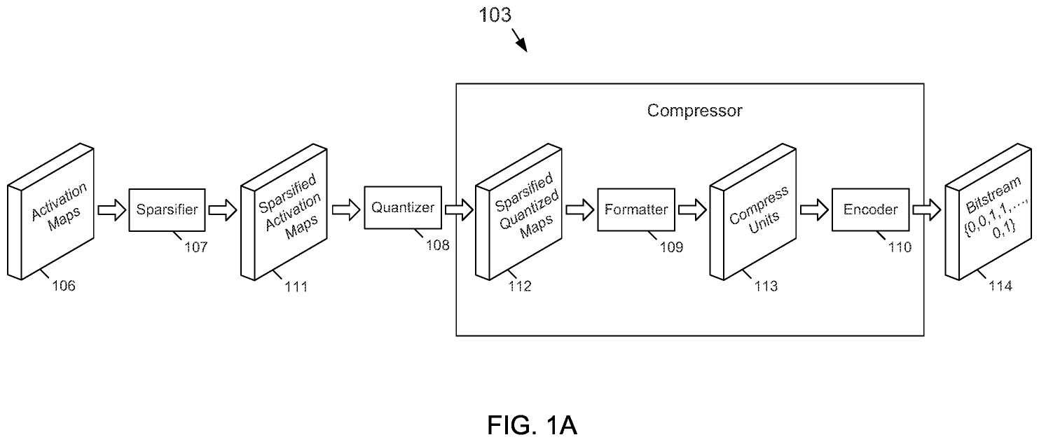

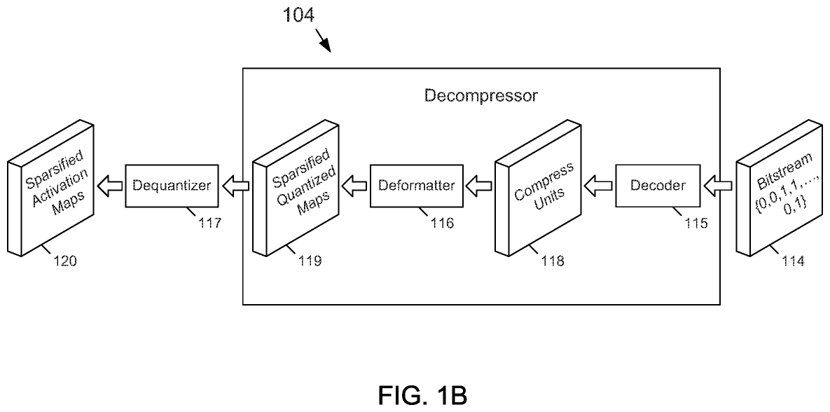

FIG. 1 depicts a functional block diagram of an example embodiment of a system 100 for lossy compression and decompression of activation maps of a neural network according to the subject matter disclosed herein. The system 100 includes a processor 101, memory 102, a compressor 103 and a decompressor 104. During training and/or during inference, the compressor 103 and the decompressor 104 respectively compresses activation maps 106 of a neural network 105 to form a bitstream 114 and decompresses the bitstream 114 to reform the activation maps. Prior to compressing an activation map, the compressor 103 and the decompressor 104 are configured to use corresponding compression and decompression modes. The system 100 may also include one or more additional processors (not shown), bulk storage (not shown) and input/output devices, such as, but not limited to, a keyboard (not shown), a display (not shown) and a pointing device (not shown).

The compressor 103 and the decompressor 104 may be embodied as modules. The term “module,” as used herein, refers to any combination of software, firmware and/or hardware configured to provide the functionality described herein in connection with a module. The software may be embodied as a software package, code and/or instruction set or instructions, and the term “hardware,” as used in any implementation described herein, may include, for example, singly or in any combination, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-chip (SoC) and so forth. Additionally, the processor 101 and the memory 102 may be components of a module forming the compressor 103 and/or the decompressor 104. Alternatively, the processor 101 and the memory 102 may be utilized by modules forming the compressor 103 and/or the decompressor 104.

FIG. 1A depicts a functional block diagram of the compressor 103 according to the subject matter disclosed herein. The compressor 103 may include a sparsifier 107, a quantizer 108, a formatter 109 and a lossless encoder 110. It should be noted that although the sparsifier 107 and the quantizer 108 are depicted in FIG. 1A as being separate from the compressor 103, in other embodiments, the sparsifier 107 and/or the quantizer 108 may be part of the compressor 103.

An activation map 106 that has been generated at a layer of the neural network 105 may be configured, for example, by the processor 101 and the memory 102, to be a tensor of a predetermined size. In one embodiment, an activation map 106 may be configured to a tensor of size H×W×C in which H corresponds to the height of the input tensor, W to the width of the input tensor, and C to the number of channels of the input tensor. The activation map 106 may be formed and stored as a single tensor of size H×W×C.

The activation maps 106 of the neural network 105 are sparsified by the sparsifier 107 to form sparsified activation maps 111 that have an increased number of values that are equal to zero so that the lossless compression performed by the encoder 110 will be more effective. The sparsifier stage 107 fine tunes a pre-trained neural network using an additional regularization in a cost function. Typically, when neural networks are trained, a cost function L(w) is minimized with respect to the weights w. The cost function L(w) contains two terms: a data term and a regularization term. The data term is usually a cross-entropy loss, while the regularization term is typically an L2 norm on the network weights. During fine-tuning of the pre-trained network, the cost function L(w) is modified by adding a new regularization term:

L′(w)=L(W)+Σⱼλⱼ∥Aⱼ∥₁ (1)

in which Aⱼ=Aⱼ·(wⱼ) is the activation map of layer j, and λⱼ are Lagrange multipliers that control the amount of sparsity.

The Lagrange multipliers λⱼ may be selected to control the amount of sparsity of the activation maps for layer j. A larger λⱼ will produce a sparse Aj. Intuitively, adding an L1 regularization on A constraints the weights w to produce a sparser output. Weights w are adjusted to form a sparser A through backpropagation. The fine-tuning starts with a pre-trained network and minimizes the modified cost function L′(w). Fine-tuning continues for several epochs (depending on the network and dataset, typically between 10-50 epochs).

If, after sparification, the values of a sparsified activation map 111 have not been quantized from floating-point numbers to be integers, the non-quantized values of the sparsified activation map 111 may be quantized by the quantizer 108 into integer values having any bit width (i.e., 8 bits, 12 bits, 16 bits, etc.) to form a sparsified and quantized activation map 112. Quantizing by the quantizer 108, if needed, may also be considered to be a way to introduce additional compression, but at the expense of accuracy. Typically linear (uniform) quantization is used and q may be anything between 1 and 16 bits. In one embodiment, the quantization may take place during runtime because new activation maps are produced for each input image.

To facilitate compression, the H×W×C sparsified and quantized activation map 112 may be formatted by the formatter 109 into blocks of values, in which each block is referred to herein as “compress units” 113. That is, a sparsified and quantized activation map 112 of tensor size H×W×C may be divided into smaller compress units. The compress units 113 may include K elements (or values) in a channel-major order in which K>0; a scanline (i.e., each block may be a row of an activation map); or K elements (or values) in a row-major order in which K>0. Other techniques or approaches for forming compress units 113 are also possible. For example, a loading pattern of activation maps for the corresponding neural-network hardware may be used as a basis for a block (or compress unit) formatting technique.

Each compress unit 113 may be losslessly encoded, or compressed, independently from other compress units by an encoder 110 to form a bitstream 114. The bit stream 114 may be stored in the memory 102 or in a memory associated with the neural network 105. Each compress unit 113 may be losslessly encoded, or compressed, using any of a number of compression techniques, referred to herein as “compression modes” or simply “modes.” Example lossless compression modes include, but are not limited to, Exponential-Golomb encoding, Sparse-Exponential-Golomb encoding, Sparse-Exponential-Golomb-RemoveMin encoding, Golomb-Rice encoding, Exponent-Mantissa encoding, Zero-encoding, Fixed length encoding and Sparse fixed length encoding. It should be understood that other lossless encoding techniques may be used either in addition or as an alternative one of the example compression modes. It should also be noted that many of the example compression modes are publically available or based on publically available compression modes, except, however, the Sparse-Exponential-Golomb and the Sparse-Exponential-Golomb-RemoveMin compression modes. Details for the Sparse-Exponential-Golomb and the Sparse-Exponential-Golomb-RemoveMin compression modes are provided herein.

The Exponential-Golomb encoding is a well-known compression mode that assigns variable length codes in which smaller numbers are assigned shorter codes. The number of bits used to encode numbers increases exponentially, and one parameter, commonly referred to as the order k parameter, controls the rate at which the number of bits increases. The pseudocode below provides example details of the Exponential-Golomb compression mode.

Let x, x >= 0 be the input, let k be the parameter (order)
Generate output bitstream: <Quotient Code><Remainder Code>:
Quotient Code:

Encode q = floor (x / 2\hat{ }k) using 0-order exp-Golomb code:
z = binary (q + 1)
numBits = len (z)
Write numBits−1 zero bits followed by z, and denote by u

Remainder Code:

Encode r = x % 2\hat{ }k in binary, and denote by f = binary (r)

Concatenate u,f to produce output bitstream

An example of the Exponential-Golomb compression mode is:
x=23, k=3
q=floor (23/2\hat{ }3)=2
z=binary (2+1)=binary (3)=11
numBits=len (z)=2
u=011 (2−1=1 zeros followed by z)
f=binary (r)=binary (23% 8)=binary (7)=111
Final output=011+111=011111

Table 1 sets forth values of the Exponential-Golomb compression mode for input values x=0-29 and for order k=0-3.

TABLE 1

| x | k = 0 | k = 1 | k = 2 | k = 3 |
|---|---|---|---|---|
| 0 | 1 | 10 | 100 | 1000 |
| 1 | 010 | 11 | 101 | 1001 |
| 2 | 011 | 0100 | 110 | 1010 |
| 3 | 00100 | 0101 | 111 | 1011 |
| 4 | 00101 | 0110 | 01000 | 1100 |
| 5 | 00110 | 0111 | 01001 | 1101 |
| 6 | 00111 | 001000 | 01010 | 1110 |
| 7 | 0001000 | 001001 | 010110 | 1111 |
| 8 | 0001001 | 001010 | 01100 | 010000 |
| 9 | 0001010 | 001011 | 01101 | 010001 |
| 10 | 0001011 | 001100 | 01110 | 010010 |
| 11 | 0001100 | 001101 | 01111 | 010011 |
| 12 | 0001101 | 001110 | 0010000 | 010100 |
| 13 | 0001110 | 001111 | 0010001 | 010101 |
| 14 | 0001111 | 00010000 | 0010010 | 010110 |
| 15 | 000010000 | 00010001 | 0010011 | 010111 |
| 16 | 000010001 | 00010010 | 0010100 | 011000 |
| 17 | 000010010 | 00010011 | 0010101 | 011001 |
| 18 | 000010011 | 00010100 | 0010110 | 011010 |
| 19 | 000010100 | 00010101 | 0010111 | 011011 |
| 20 | 000010101 | 00010110 | 0011000 | 011100 |
| 21 | 000010110 | 00010111 | 0011001 | 011101 |
| 22 | 000010111 | 00011000 | 0011010 | 011110 |
| 23 | 000011000 | 00011001 | 0011011 | 011111 |
| 24 | 000011001 | 00011010 | 0011100 | 00100000 |
| 25 | 000011010 | 00011011 | 0011101 | 00100001 |
| 26 | 000011011 | 00011100 | 0011110 | 00100010 |
| 27 | 000011100 | 00011101 | 0011111 | 00100011 |
| 28 | 000011101 | 00011110 | 000100000 | 00100100 |
| 29 | 000011110 | 00011111 | 000100001 | 00100101 |

The Sparse-Exponential-Golomb compression mode is an extension, or variation, of Exponential-Golomb compression mode in which if the value x that is to be encoded is a 0, the value x is represented by a “1” in the output bitstream. Otherwise, Exponential-Golomb encoding adds a “0” and then encodes the value x−1 using standard Exponential-Golomb. In one embodiment in which block (compress unit) values are eight bits, an order k=4 may provide the best results.

The Sparse-Exponential-Golomb-RemoveMin compression mode is an extension, or variation, to the Sparse-Exponential-Golomb compression mode that uses the following rules: (1) Before values are encoded in a compress unit, the minimum non-zero value is determined, which may be denoted by the variable y. (2) The variable y is then encoded using Exponential-Golomb compression mode. (3) If the value x that is to be encoded is a 0, then it is encoded as a “1,” and (4) otherwise a “0” is added to the bitstream and then x - y is encoded using the Exponential-Golomb compression mode.

The Golomb-Rice compression mode and the Exponent-Mantissa compression mode are well-known compression algorithms. The pseudocode below sets forth example details of the Golomb-Rice compression mode.

Let x, x >= 0 be the input and M be the parameter. M is a power of 2.
q = floor (x / M)
r = x % M
Generate output bitstream: <Quotient Code><Remainder Code>:

Quotient Code:

Write q-length string of 1 bits
Write a 0 bit

Remainder Code: binary (r) in log₂ (M) bits

An example of the Golomb-Rice compression mode is:
x=23, M=8, log₂ (M)=3
q=floor (23/8)=2
r=7
Quotient Code: 110
Remainder Code: 111
Output=110111

The Zero-encoding compression mode checks whether the compress unit is formed entirely of zeros and, if so, an empty bitstream is returned. It should be noted that the Zero-compression mode cannot be used if a compress unit contains at least one non-zero value.

The Fixed length encoding compression mode is a baseline, or default, compression mode that performs no compression, and simply encodes the values of a compress unit using a fixed number of bits.

Lastly, the sparse fixed length encoding compression mode is the same as Fixed length encoding compression mode, except if a value x that is to be encoded is a 0, then it is encoded as a 1, otherwise, a 0 is added and a fixed number of bits are used to encode the non-zero value.

Referring back to FIG. 1A, in one embodiment the encoder 110 may start the compressed bitstream 114 with 48 bits in which 16 bits may be used respectively denote H, W and C of the input tensor. Each compress unit 113 may be compressed iteratively for each compression mode that may be available. The compression modes available for each compress unit may be fixed during compression of an activation map. In one embodiment, the full range of available compression modes may be represented by L bits. If, for example, four compression modes are available, a two bit prefix may be used to indicate corresponding indices (i.e., 00, 01, 10 and 11) for the four available compression modes. In an alternative embodiment, a prefix variable length coding technique may be used to save some bits. For example, the index of the compression mode most commonly used by the encoder 108 may be represented by a “0”, and the second, third and fourth most commonly used compression mode respectively represented by a “10,” “110” and “111.” If only one compression mode is used, then appending an index to the beginning of a bitstream 114 for a compress unit would be unnecessary.

In one embodiment, when a compress unit 113 is compressed, all available compression modes may be run and the compression mode that has generated the shortest bitstream may be selected. The corresponding index for the selected compression mode may be appended as a prefix to the beginning of the bitstream for the particular compress unit and then the resulting bitstream for the compress unit may be added to the bitstream for the entire activation map. The process may then be repeated for all compress units for the activation map. Each respective compress unit of an activation map may be compressed using a compression mode that is different from the compression mode used for an adjacent, or neighboring, compress unit. In one embodiment, a small number of compression modes, such as two compression modes, may be available to reduce the complexity of compressing the activation maps.

FIG. 1B depicts a functional block diagram of the decompressor 104 according to the subject matter disclosed herein. The decompressor 104 decompresses a bitstream 114 to form activation maps 120 for a neural network 105′ (FIG. 1), which are lossy decompressions corresponding to the original non-sparsified activation maps 106. Thus, the neural network 105′ may be a modified version of the original neural network 105.

The decompressor 104 may include a decoder 115, a deformatter 116 and a dequantizer 117. It should be noted that although the dequantizer 117 is depicted in FIG. 1B as being separate from the decompressor 104, in other embodiments, the dequantizer 117 may be part of the decompressor 104.

In one embodiment, the decompressor 104 reads the first 48 bits of the bitstream 114 to retrieve H, W and C, and then processes the bitstream 114 one compress unit at a time. The decompressor 104 has knowledge of both the number of bits for the index of the mode and of the number of elements in a compress unit (either W or K depending on the compression mode used). That is, the bitstream 114 corresponding to the original (sparsified) activation map 106 is decompressed by the decoder 115 to form a compress unit 118. The compress unit 118 is deformatted by a deformatter 116 to form a sparsified and quantized activation map 119 having a tensor of size H×W×C. The sparsified and quantized activation map 119 may dequantized by the dequantizer 117 to form a sparsified activation map 120 that corresponds to the original sparsified activation map 106. It should be noted that the sparsified activation map 120 is a lossy decompression of a corresponding original non-sparsified activation map 106.

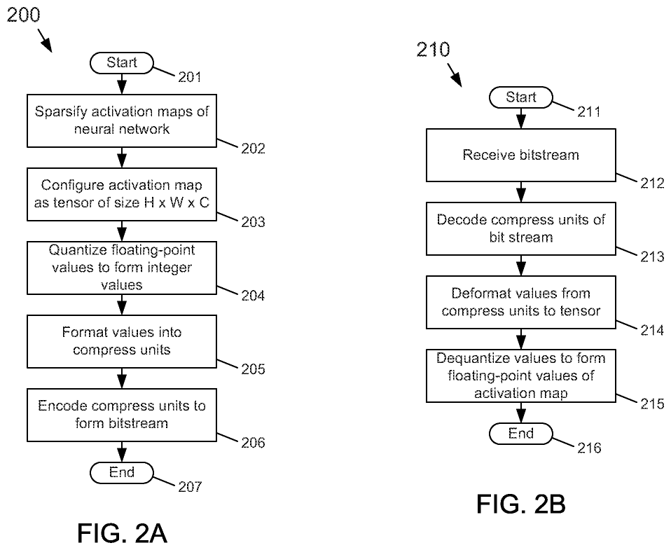

FIGS. 2A and 2B respectively depict example embodiments of an encoding method 200 and a decoding method 210 of activation maps of a deep neural network according to the subject matter disclosed herein. The activation map for each layer of the neural network may be processed by the encoding/decoding method pair of FIGS. 2A and 2B. Prior to compressing an activation map, the compressor 103 and the decompressor 104, such as depicted in FIGS. 1A and 1B, are configured to use corresponding compression and decompression modes.

In FIG. 2A, the process starts at 201. At 202, the activation maps of a neural network are sparsified to form sparsified activation maps that have an increased number of values that are equal to zero so that the lossless compression performed later will be more effective. One example sparsification technique is described in connection with Eq. (1). Other sparsification techniques may be used.

At 203, a sparsified activation map is configured to be encoded. In one embodiment, the sparsified activation map that has been generated at a layer of a neural network is configured to be a tensor of size H×W×C in which H corresponds to the height of the input tensor, W to the width of the input tensor, and C to the number of channels of the input tensor. If the values of the sparsified activation map have not been quantized from floating-point numbers to be integers, then at 204 the non-quantized values of the sparsified activation map may be quantized into integer values having any bit width to form a sparsified quantized activation map.

At 205, the sparsified quantized activation map may be formatted into compress units. At 206, each compress unit may be losslessly encoded, or compressed, independently from other compress units to form a bitstream. Each compress unit may be losslessly encoded, or compressed, using any of a number of compression modes. Example lossless compression modes include, but are not limited to, Exponential-Golomb encoding, Sparse-Exponential-Golomb encoding, Sparse-Exponential-Golomb-RemoveMin encoding, Golomb-Rice encoding, Exponent-Mantissa encoding, Zero-encoding, Fixed length encoding and Sparse fixed length encoding. Each compress unit is compressed iteratively for each compression mode that may be available. In one embodiment, when a compress unit is compressed, all available compression modes may be run and the compression mode that has generated the shortest bitstream may be selected. When all compress units for the activation map have been encoded, the process ends for the activation map at 207. The process 200 of FIG. 2A continues in the same manner for each activation map of the neural network.

In FIG. 2B, the process begins at 211. At 212, a bitstream is received and the first 48 bits are read to retrieve an encoded compress unit. At 213, each encoded compress unit is decoded to form a decoded compress unit. At 214, each decoded compress unit is deformatted to form a sparsified and quantized activation map. At 215 the values are dequantized to form a sparsified dequantized activation map. The process ends for the activation map at 216. The process 210 of FIG. 2B continues in the same manner to decompress each activation map of the neural network.

The following example pseudocode corresponds to the method 200.

```
#Tensor T has size HxWxC
def compress (T):
bitstream = “”
for each channel, c, in C
  CU = formatMaps(c)
  for each cu in CU
  bitstream + = compressCU(cu)
return bitstream
def compressCU(cu)
  bitstreams =
generateBitstreamsforAllComprModes(cu)
  minBitstreamIdx, minBitstream =
shortestBitstream(bitstreams)
  mode = binary(minBitstreammIdx)
  bitstream = mode + minBitstream
  return bitstream
```

}

The following example pseudocode corresponds to the method 210.

```
def decompress(bitstream):
  H,W,C = getActivationMapShape(bitstream[0:48])
  bitstream = bitstream[48:]
  CU = [ ]
  while bitstream 1 = “”:
```

cu , bitstream = decompressCU(bitstream)
CU.append(cu)

return deformatCU (CU, H, W, C)

# decompressUnit already knows how many compression modes are used and how many bits are used as header to indicate index of compression mode. In one embodiment, the number of compression modes used is the number L.
# decompressUnit also knows how many elements are contained in a compress unit, in this example the number of elements is K.
# decodeNextValue (bitstream, modeIdx) uses the modeIdx to choose the correct decoder to decode the next value. It also strips the bits used from bitstream. It returns the decoded value and the stripped bitstream.

```
def decompressCU (bitstream):
  modeIdx=getComprModeIndex(bitstream[0:L])
  bitstream=bitstream[L:]
  cu = [ ]
  for k in range (K):
```

val, bitstream = decodeNextValue (bitstream , modeIdx)
cu.append (val)

return cu , bitstream

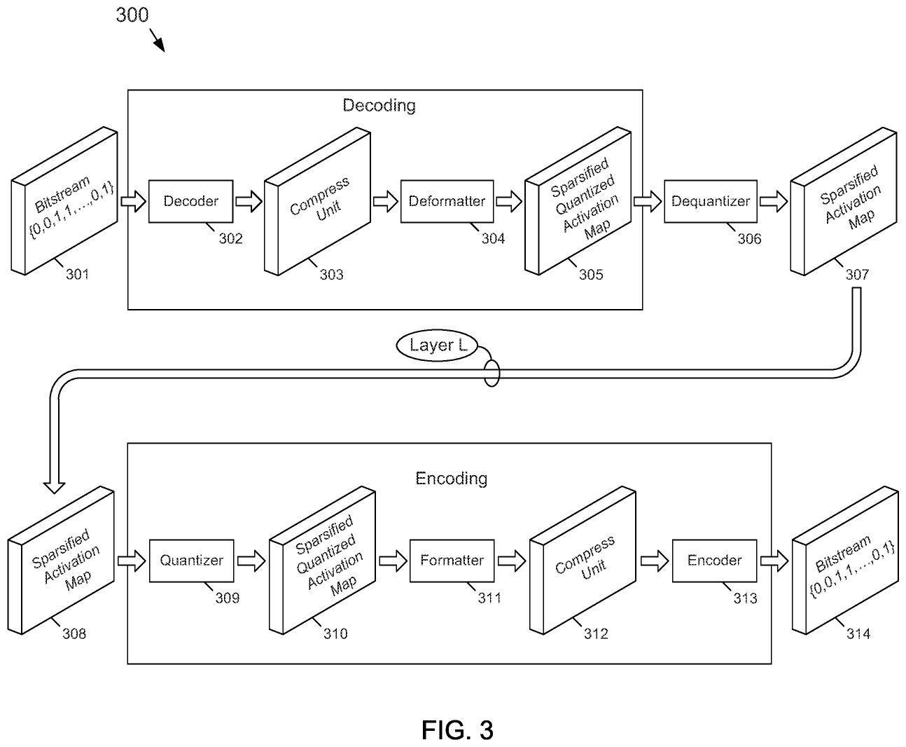

FIG. 3 depicts an operational flow 300 of an activation map at a layer L of a neural network according to the subject matter disclosed herein. The operational flow 300 represents both forward and backward processing directions through the layer L. That is, the operational flow 300 represents an operational flow for training a neural network and for forming an inference from an input to the neural network. An encoded (sparsified and compressed) representation of an original activation map (not shown) of a neural network is turned into a bitstream 301 as it is read out of a memory, such as memory 102 in FIG. 1. At 302, the bitstream is decoded to form compress units 303. The compress units 303 are deformatted at 304 to form a sparsified quantized activation map 305. (Again, it should be noted that quantizing of an activation map may be optional.) At 306, the sparsified and quantized activation map 305 is dequantized to form a sparsified activation map 307 for the layer L.

The sparsified activation map 307 is used at layer L of the neural network to compute an output activation map 308. The output activation map 308 is (optionally) quantized at 309 to form a sparsified and quantized activation map 310. The sparsified and quantized activation map 310 is formatted at 311 to form compress units 312. The compress units 312 are encoded at 313 to form a bitstream 314, which is stored a memory, such as, memory 102 in FIG. 1.

As will be recognized by those skilled in the art, the innovative concepts described herein can be modified and varied over a wide range of applications. Accordingly, the scope of claimed subject matter should not be limited to any of the specific exemplary teachings discussed above, but is instead defined by the following claims.

What is claimed is:

1. A system to compress an activation map of a layer of a neural network, the system comprising:
a processor programmed to initiate executable operations comprising:
sparsifying, using the processor, a number of non-zero values of the activation map;
configuring the activation map as a tensor having a tensor size of H×W×C in which H represents a height of the tensor, W represents a width of the tensor, and C represents a number of channels of the tensor;
formatting the tensor into at least one block of values; and
encoding the at least one block independently from other blocks of the tensor using at least one lossless compression mode.

2. The system of claim 1, wherein the at least one lossless compression mode is selected from a group including Exponential-Golomb encoding, Sparse-Exponential-Golomb encoding, Sparse-Exponential-Golomb-RemoveMin encoding, Golomb-Rice encoding, Exponent-Mantissa encoding, Zero-encoding, Fixed length encoding, and Sparse fixed length encoding.

3. The system of claim 2, wherein the at least one lossless compression mode selected to encode the at least one block is different from a lossless compression mode selected to encode another block of the tensor.

4. The system of claim 2, wherein encoding the at least one block comprises encoding the at least one block encoded independently from other blocks of the tensor using a plurality of the lossless compression modes.

5. The system of claim 2, wherein the at least one block comprises 48 bits.

6. The system of claim 1, wherein the executable operations further comprise outputting the at least one block encoded as a bit stream.

7. The system of claim 6, wherein executable operations further comprise:
decoding the at least one block independently from other blocks of the tensor using at least one decompression mode corresponding to the at least one compression mode used to compress the at least one block; and
deformatting the at least one block into a tensor having the size of H×W×C.

8. The system of claim 1, wherein the sparsified activation map includes floating-point values, and
wherein the executable operations further comprise quantizing the floating-point values of the activation map to be integer values.

9. A method to compress an activation map of a neural network, the method comprising:
sparsifying, using a processor, a number of non-zero values of the activation map;
configuring the activation map as a tensor having a tensor size of H×W×C in which H represents a height of the tensor, W represents a width of the tensor, and C represents a number of channels of the tensor;
formatting the tensor into at least one block of values; and
encoding the at least one block independently from other blocks of the tensor using at least one lossless compression mode.

10. The method of claim 9, further comprising selecting the at least one lossless compression mode from a group including Exponential-Golomb encoding, Sparse-Exponential-Golomb encoding, Sparse-Exponential-Golomb-RemoveMin encoding, Golomb-Rice encoding, Exponent-Mantissa encoding, Zero-encoding, Fixed length encoding, and Sparse fixed length encoding.

11. The method of claim 10, wherein the at least one lossless compression mode selected to encode the at least one block is different from a lossless compression mode selected to compress another block of the tensor.

12. The method of claim 10, wherein encoding the at least one block further comprises encoding the at least one block independently from other blocks of the tensor using a plurality of the lossless compression modes.

13. The method of claim 10, wherein the at least one block comprises 48 bits.

14. The method of claim 9, further comprising outputting the at least one block encoded as a bit stream.

15. The method of claim 14, further comprising:
decompressing, using the processor, the at least one block independently from other blocks of the tensor using at least one decompression mode corresponding to the at least one compression mode used to compress the at least one block; and
deformatting the at least one block into a tensor have the size of H×W×C.

16. The method of claim 9, wherein the activation map includes floating-point values,
the method further comprising quantizing the floating-point values of the activation map to be integer values.

17. A method to decompress a sparsified activation map of a neural network, the method comprising:
decompressing, using a processor, a compressed block of values of a bitstream representing values of the sparsified activation map to form at least one decompressed block of values, the decompressed block of values being independently decompressed from other blocks of the activation map using at least one decompression mode corresponding to at least one lossless compression mode used to compress the at least one block; and
deformatting the decompressed block to be part of a tensor having a size of H×W×C in which H represents a height of the tensor, W represents a width of the tensor, and C represents a number of channels of the tensor, the tensor being the decompressed activation map.

18. The method of claim 17, wherein the at least one lossless compression mode is selected from a group including Exponential-Golomb encoding, Sparse-Exponential-Golomb encoding, Sparse-Exponential-Golomb-RemoveMin encoding, Golomb-Rice encoding, Exponent-Mantissa encoding, Zero-encoding, Fixed length encoding, and Sparse fixed length encoding.

19. The method of claim 18, further comprising:
sparsifying, using the processor, a number of non-zero values of the activation map;
configuring the activation map as a tensor having a tensor size of H×W×C;
formatting the tensor into at least one block of values; and
encoding the at least one block independently from other blocks of the tensor using at least one lossless compression mode.

20. The method of claim 19, wherein the at least one lossless compression mode selected to compress the at least one block is different from a lossless compression mode selected to compress another block of the tensor of the received at least one activation map, and
wherein compressing the at least one block further comprises compressing the at least one block independently from other blocks of the tensor of the received at least one activation map using a plurality of the lossless compression modes.
